(19) United States
(12) Patent Application Publication
(10) Pub. No.: US 2026/0352196 A1
(43) Pub. Date: Nov. 5, 2026

(54) MICROCONTROLLER UNIT WITH IMPROVED CLOCK MODULATION

(71) Applicant: Monolithic Power Systems, Inc., Kirkland, WA (US)

(72) Inventor: Régis Caillet, Bevaix (CH)

(21) Appl. No.: 19/195,054

(22) Filed: Apr. 30, 2025

(51) Int. Cl. H03K 7/08; H03L 7/099

(52) U.S. Cl. CPC H03K 7/08; H03L 7/099

(57) ABSTRACT

A microcontroller unit providing a modulation waveform to modulate a clock signal is discussed. The clock signal is used to control a power converter. The modulation waveform may have any desired shapes and modulation depth by setting different values in a plurality of registers, so that the clock signal is modulated with a desired manner.

### BACKGROUND OF THE INVENTION

Switching mode power supplies are used in various applications. In order to get small volume and high efficiency, the switching frequency of the switching mode power supplies are rather high, e.g. tens of thousands of hertz. However, such high switching frequency may cause severe EMI problems, which decreases electrical quality, influences electronic equipment around switching mode power supplies, interferes with radio waves, etc. As a result, strict EMI standards have been adopted in many countries. Spread-spectrum clocks have been a valuable technology for the purposes of EMI reduction and EMC compliance.

Conventional spectrum shape technology typically uses a triangle modulation profile, which causes the switching mode power supplies to be stuck to this profile.

### SUMMARY OF THE INVENTION

In accordance with an embodiment of the present invention, a microcontroller unit is discussed. The microcontroller unit comprises: a PLL circuit, configured to modulate a source clock signal with a modulation profile, to generate a modulated clock signal, wherein the modulation profile has a configurability with variable values.

In addition, in accordance with an embodiment of the present invention, a modulation waveform generator used in a microcontroller unit is discussed. The modulation waveform generator comprises: an address counter, a selector, and an arithmetic unit. The address counter is configured to provide (M−1) pointers from N to (N+M−2) or from (N+M−1) to (N+1) in response to (M−1) clock signals, wherein N is an integer equal to or larger than 0, and M is an integer number larger than 1. The selector is configured to select different values from a series of registers in response to each of the pointers, to provide (M-1) waveform values. The arithmetic unit is configured to perform an arithmetic operation on waveform values and an initial divider factor, to provide a modulation waveform.

Furthermore, in accordance with an embodiment of the present invention, a microcontroller unit is discussed. The microcontroller unit comprises: a PLL circuit and a modulation waveform generator. The PLL circuit is configured to modulate a source clock signal with a modulation profile, to generate a modulated clock signal. The modulation profile has a configurability with variable values. The modulation waveform generator is configured to generate a modulation waveform in response to a series of clock signals. The modulation waveform is operable to provide the configurability of the modulation profile.

### BRIEF DESCRIPTION OF DRAWINGS

FIG. 1 schematically shows a microcontroller unit system 100 in the prior art.

FIG. 2 schematically shows a microcontroller unit system 200 with a detailed circuit configuration of the PLL circuit 102 in accordance with an embodiment of the present invention.

FIG. 3 schematically shows a microcontroller unit system 300 with a detailed circuit configuration of the controller 103 in accordance with an embodiment of the present invention.

FIG. 4 schematically shows a microcontroller unit system 400 with a detailed circuit configuration of the controller 103 in accordance with an embodiment of the present invention.

FIG. 5 schematically shows a flowchart 500 of a method for generating a modulation waveform to modulate a clock signal in accordance with an embodiment of the present invention.

### DETAILED DESCRIPTION OF THE INVENTION

Embodiments of circuits for microcontroller unit system are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

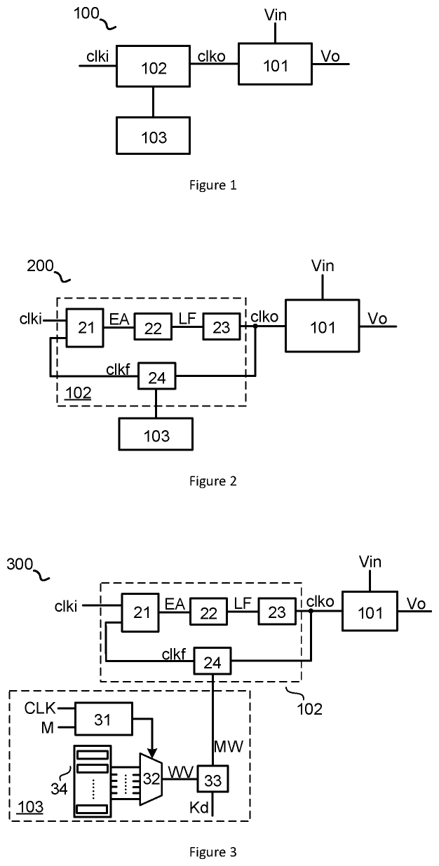

FIG. 1 schematically shows a microcontroller unit system 100 in accordance with an embodiment of the present invention. In the example of FIG. 1, the microcontroller unit system 200 comprises: a power converter 101, configured to convert an input voltage Vin to an output voltage Vo; and a PLL (phase locked loop) circuit 102, configured to modulate a source clock signal clki with a variable modulation profile (i.e., a variable modulation shape), to generate a modulated clock signal clko. The modulated clock signal clko is configured to control the power converter 101.

In one embodiment of the present invention, a controller 103 is configured to load a modulation waveform with variable values to the PLL circuit 102, to provide a configurability of the modulation profile. The controller 103 may comprise a look up table (LUT) to store the values of the modulation waveform. The modulation waveform is periodic. The LUT may comprise a plurality of registers.

FIG. 2 schematically shows a microcontroller unit system 200 with a detailed circuit configuration of the PLL circuit 102 in accordance with an embodiment of the present invention. As shown in FIG. 2, the PLL circuit 102 comprises: a phase detector 21, a filter 22, a voltage-controlled oscillator 23, and a divider 24. The phase detector 21 is configured to detect a phase difference between the source clock signal clki and a feedback signal clkf, to generate an error signal EA. The filter 22 is configured to filter the error signal EA, to generate a filtered signal LF. The voltage-controlled oscillator 23 is configured to generate the modulated clock signal clko in response to the filtered signal LF. The divider 24 is configured to modulate the modulated clock signal clko under the control of the controller 103, to generate the feedback signal clkf.

In one embodiment of the present invention, the controller 103 may provide a divider factor having variable values along the modulation waveform to the divider 24, so as to have the divider 24 modulate the modulated clock signal clko with the divider factor. In one embodiment of the present invention, the divider factor may be derived from the modulation waveform.

FIG. 3 schematically shows a microcontroller unit system 300 with a detailed circuit configuration of the controller 103 in accordance with an embodiment of the present invention. In the example of FIG. 3, the controller 103 comprises: a modulation waveform generator, configured to generate the modulation waveform MW in response to a series of clock signals CLK and an initial divider factor Kd. The modulation waveform generator is configured to select different values from different registers in response to each clock signal.

In one embodiment of the present invention, the clock signal may be a system clock (e.g., the source clock signal clki). In other embodiments of the present invention, the clock signal may be derived from the system clock (e.g. by way of a frequency divider) and have a frequency lower than the system clock. For example, the clock signal may be a sub-frequency of the system clock. For example, the clock signal may have a frequency that is half or ¼ of the system clock.

Specifically, as shown in FIG. 3, the modulation waveform generator comprises: an address counter 31, a selector 32, and an arithmetic unit 33. The address counter 31 is configured to provide (M−1) pointers from N to (N+M−2) or from (N+M−1) to (N+1) in response to a series of clock signals CLK, wherein N is an integer equal to or larger than 0, and M is an integer number larger than 1. The selector 32 is configured to select different values from a series of registers 34 in response to each of the pointers, to provide a series of waveform values WV. The arithmetic unit 35 is configured to perform an arithmetic operation on waveform values MV and the initial divider factor Kd, to provide the modulation waveform MW. The arithmetic operation may comprise an add operation and a subtract operation.

In one embodiment of the present invention, the number M may be in a digital form with 6 bits; each of the registers stores a value that may also be a digital number with 6 bits. The divider factor may be in a digital form with more than 6 bits, e.g. it is 10-bits.

In one embodiment of the present invention, the modulation waveform MW has a modulation cycle with 4 quarters: a first quarter, a second quarter, a third quarter, and a fourth quarter. Each quarter has a time period that is (M−1) times of a clock cycle of the clock signal CLK. In the first quarter, the address counter 31 is configured to provide a series of pointers from N to (N+M−2). Accordingly, the selector 32 is configured to select the corresponding registers, and read the specific waveform values from the registers.

Then the arithmetic unit 35 is configured to add the waveform values MV to the initial divider factor Kd in response to each clock signal CLK. In the second quarter, the address counter 33 is configured to provide a series of pointers from (N+M−1) to (N+1), and the arithmetic unit 35 is configured to add the waveform values MV to the initial divider factor Kd in response to each clock signal CLK. In the third quarter, the address counter 33 is configured to provide a series of pointers from N to (N+M−2), and the arithmetic unit 35 is configured to subtract the waveform values MV from the initial divider factor Kd in response to each clock signal CLK. In the fourth quarter, the address counter 33 is configured to provide a series of pointers from (N+M−1) to (N+1), and the arithmetic unit 35 is configured to subtract the waveform values MV to the initial divider factor Kd in response to each clock signal CLK.

Thus, by setting the waveform values in the registers, the modulation wave with any desired modulation shape and modulation depth is applied.

In one embodiment of the present invention, the microcontroller unit system may be configured to provide the modulation waveform to the divider when the application is needed. The microcontroller unit system may also provide a fixed divider factor to the divider when needed.

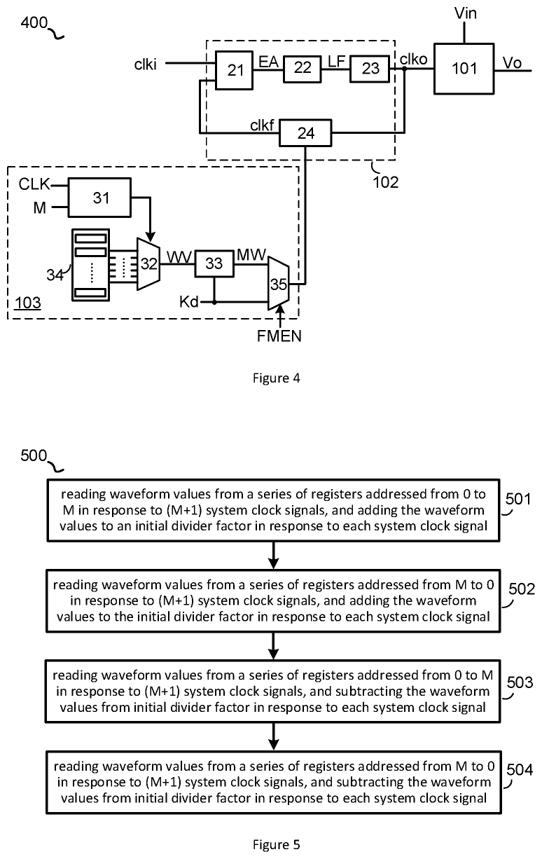

FIG. 4 schematically shows a microcontroller unit system 400 with a detailed circuit configuration of the controller 103 in accordance with an embodiment of the present invention. The microcontroller unit system 400 in FIG. 4 is similar to the microcontroller unit system 300 in FIG. 3, with a difference that in the example of FIG. 4, the controller 103 further comprises a select circuit 35, configured to select the initial divider factor Kd or select a value from the modulation waveform MW in response to an enable signal FMEN.

In one embodiment of the present invention, the divider 24 is configured to modulate the modulated clock signal clko with the modulation waveform when the enable signal FMEN is set high, and the divider 24 is configured to modulate the modulated clock signal clko with a fixed divider factor (e.g., the initial divider factor Kd) when the enable signal FMEN is set low.

FIG. 5 schematically shows a flowchart 500 of a method for generating a modulation waveform to modulate a clock signal in accordance with an embodiment of the present invention. The method comprises:
Step 501, reading waveform values from a series of registers addressed from N to (N+M−2) in response to (M−1) clock signals, and adding the waveform values to an initial divider factor in response to each clock signal. N is an integer equal to or larger than 0, and M is an integer number larger than 1.
Step 502, reading waveform values from a series of registers addressed from (N+M−1) to (N+1) in response to (M−1) clock signals, and adding the waveform values to the initial divider factor in response to each clock signal.
Step 503, reading waveform values from a series of registers addressed from N to (N+M−2) in response to (M−1) clock signals, and subtracting the waveform values from initial divider factor in response to each clock signal. And
Step 504, reading waveform values from a series of registers addressed from (N+M−1) to (N+1) in response to (M−1) clock signals, and subtracting the waveform values from initial divider factor in response to each clock signal.

In one embodiment of the present invention, the method further comprises: selecting the modulation waveform or the initial divider factor to modulate the clock signal in response to an enable signal FMEN.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

1. A microcontroller unit, comprising:
a PLL circuit, configured to modulate a source clock signal with a modulation profile, to generate a modulated clock signal, wherein the modulation profile has a configurability with variable values; and
a controller, configured to load a modulation waveform with variable values to the PLL circuit, to provide the configurability of the modulation profile; wherein the controller comprises:
a modulation waveform generator, configured to generate the modulation waveform in response to a series of system clock signals or to a series of derivative clock signals from the system clock signals, wherein the modulation waveform generator is configured to select different values from different registers in response to each of the system clock signals or to each of the derivative clock signals.

2. (canceled)

3. (canceled)

4. The microcontroller unit of claim 1, wherein the controller further comprises:
a select circuit, configured to select an initial divider factor or select a value from the modulation waveform in response to an enable signal.

5. The microcontroller unit of claim 1, wherein the modulation waveform generator comprises:
an address counter, configured to provide (M−1) pointers from N to (N+M−2) or from (N+M−1) to (N+1) in response to (M−1) clock signals, wherein N is an integer equal to or larger than 0, and M is an integer number larger than 1;
a selector, configured to select different values from a series of registers in response to each of the pointers, to provide (M−1) waveform values; and
an arithmetic unit, configured to perform an arithmetic operation on waveform values and an initial divider factor, to provide the modulation waveform.

6. The microcontroller unit of claim 5, wherein the modulation waveform has a modulation cycle with four quarters, and wherein each quarter has a time period that is (M−1) times of a clock cycle of the system clock signal or of the derivate clock signal.

7. The microcontroller unit of claim 5, wherein the modulation waveform has a modulation cycle with four quarters, and wherein:
in a first quarter, the address counter is configured to provide (M−1) pointers from N to (N+M−2), and the arithmetic unit is configured to add the waveform values to the initial divider factor in response to [each clock signal]each of the system clock signals or to each of the derivative clock signals;
in a second quarter, the address counter is configured to provide (M−1) pointers from (N+M−1) to (N+1), and the arithmetic unit is configured to add the waveform values to the initial divider factor in response to [each clock signal]each of the system clock signals or to each of the derivative clock signals;
in a third quarter, the address counter is configured to provide (M−1) pointers from N to (N+M−2), and the arithmetic unit is configured to subtract the waveform values from the initial divider factor in response to [each clock signal]each of the system clock signals or to each of the derivative clock signals; and
in a fourth quarter, the address counter is configured to provide (M−1) pointers from (N+M−1) to (N+1), and the arithmetic unit is configured to subtract the waveform values to the initial divider factor in response to [each clock signal]each of the system clock signals or to each of the derivative clock signals.

8. The microcontroller unit of claim 1, wherein the PLL circuit comprises:
a divider, configured to modulate the modulated clock signal with a divider factor.

9. The microcontroller unit of claim 8, wherein the divider factor is derived from a modulation waveform generated by a controller.

10. The microcontroller unit of claim 9, wherein the controller comprises:
a modulation waveform generator, configured to generate the modulation waveform in response to a series of [clock signals]system clock signals or to a series of derivative clock signals from the system clock signals, wherein the modulation waveform generator is configured to select different values from different registers in response to [each clock signal]each of the system clock signals or to each of the derivative clock signals.

11. The microcontroller unit of claim 9, wherein the controller comprises:
a select circuit, configured to select an initial divider factor or select a value from the modulation waveform as the divider factor in response to an enable signal.

12. A modulation waveform generator used in a microcontroller unit, comprising:
an address counter, configured to provide (M−1) pointers from N to (N+M−2) or from (N+M-1) to (N+1) in response to (M−1) clock signals, wherein N is an integer equal to or larger than 0, and M is an integer number larger than 1;
a selector, configured to select different values from a series of registers in response to each of the pointers, to provide (M−1) waveform values; and
an arithmetic unit, configured to perform an arithmetic operation on waveform values and an initial divider factor, to provide a modulation waveform.

13. The modulation waveform generator of claim 12, further comprising: a select circuit, configured to select the initial divider factor or select a value from the modulation waveform in response to an enable signal.

14. The modulation waveform generator of claim 12, wherein the modulation waveform has a modulation cycle with four quarters, and wherein each quarter has a time period that is (M−1) times of a clock cycle of the system clock signal or of the derivate clock signal.

15. The modulation waveform generator of claim 12, wherein the modulation waveform has a modulation cycle with four quarters, and wherein:
in a first quarter, the address counter is configured to provide (M−1) pointers from N to (N+M−2), and the arithmetic unit is configured to add the waveform values to the initial divider factor in response to [each clock signal]each of the system clock signals or to each of the derivative clock signals;
in a second quarter, the address counter is configured to provide (M−1) pointers from (N+M−1) to (N+1), and the arithmetic unit is configured to add the waveform values to the initial divider factor in response to [each clock signal]each of the system clock signals or to each of the derivative clock signals;
in a third quarter, the address counter is configured to provide (M−1) pointers from N to (N+M−2), and the arithmetic unit is configured to subtract the waveform values from the initial divider factor in response to [each clock signal]each of the system clock signals or to each of the derivative clock signals; and
in a fourth quarter, the address counter is configured to provide (M−1) pointers from (N+M−1) to (N+1), and the arithmetic unit is configured to subtract the waveform values to the initial divider factor in response to [each clock signal]each of the system clock signals or to each of the derivative clock signals.

16. A microcontroller unit, comprising:
a PLL circuit, configured to modulate a source clock signal with a modulation profile, to generate a modulated clock signal, wherein the modulation profile has a configurability with variable values; and
a modulation waveform generator, configured to generate a modulation waveform in response to a series of [clock signals]system clock signals or to a series of derivative clock signals from the system clock signals, wherein the modulation waveform is operable to provide the configurability of the modulation profile by selecting different values from different registers in response to each of the system clock signals or to each of the derivative clock signals.

17. The microcontroller unit of claim 16, further comprising:
a select circuit, configured to select an initial divider factor or select a value from the modulation waveform in response to an enable signal.

18. The microcontroller unit of claim 16, wherein the modulation waveform generator comprises:
an address counter, configured to provide (M−1) pointers from N to (N+M−2) or from (N+M-1) to (N+1) in response to (M-1) clock signals, wherein N is an integer equal to or larger than 0, and M is an integer number larger than 1;
a selector, configured to select different values from a series of registers in response to each of the pointers, to provide (M−1) waveform values; and
an arithmetic unit, configured to perform an arithmetic operation on waveform values and an initial divider factor, to provide the modulation waveform.

19. The microcontroller unit of claim 16, wherein the modulation waveform has a modulation cycle with four quarters, and wherein:
in a first quarter, the address counter is configured to provide (M−1) pointers from N to (N+M−2), and the arithmetic unit is configured to add the waveform values to the initial divider factor in response to [each clock signal]each of the system clock signals or to each of the derivative clock signals;
in a second quarter, the address counter is configured to provide (M−1) pointers from (N+M−1) to (N+1), and the arithmetic unit is configured to add the waveform values to the initial divider factor in response to [each clock signal]each of the system clock signals or to each of the derivative clock signals;
in a third quarter, the address counter is configured to provide (M−1) pointers from N to (N+M−2), and the arithmetic unit is configured to subtract the waveform values from the initial divider factor in response to [each clock signal]each of the system clock signals or to each of the derivative clock signals; and
in a fourth quarter, the address counter is configured to provide (M−1) pointers from (N+M−1) to (N+1), and the arithmetic unit is configured to subtract the waveform values to the initial divider factor in response to [each clock signal]each of the system clock signals or to each of the derivative clock signals.

20. The microcontroller unit of claim 16, wherein the modulation waveform has a modulation cycle with four quarters, and wherein each quarter has a time period that is (M−1) times of a clock cycle of the system clock signal or of the derivate clock signal.
